(19) United States
(12) Patent Application Publication
(10) Pub. No.: US 2026/0211333 A1
(43) Pub. Date: Jul. 23, 2026

(54) SEMICONDUCTOR PROCESSING APPARATUS

(71) Applicant: Samsung Electronics Co., Ltd., Suwon-si (KR)

(72) Inventors: Hokyun Kim, Suwon-si (KR); Wonkwon Shin, Cheonan-si (KR); Kyoungwhan Oh, Suwon-si (KR); Takashi Sasa, Suwon-si (KR)

(73) Assignees: Samsung Electronics Co., Ltd., Suwon-si (KR); SEMES CO., LTD., Cheonan-si (KR)

(21) Appl. No.: 19/292,210

(22) Filed: Aug. 6, 2025

(30) Foreign Application Priority Data
Jan. 23, 2025 (KR) 10-2025-0010485

(51) Int. Cl. G03F 7/16

(52) U.S. Cl. CPC G03F 7/162

(57) ABSTRACT

A semiconductor processing apparatus includes a storage container storing a photoresist, a supply control unit including pump devices, at least one pump controller controlling the pump devices, a system substrate connected to the pump devices and the at least one pump controller, and a bulkhead structure defining first and second space, wherein the pump devices are disposed in the first space and the at least one pump controller is disposed in the second space, and a spin coating unit including a stage on which a wafer is disposed, and a nozzle discharging the photoresist onto the wafer. The system substrate includes first and second surfaces, first connectors directly connected to a first group of pump devices, and second connectors directly connected to a second group of pump devices. Each first connector and each second connector are arranged alternately in the first direction.

### CROSS-REFERENCE TO RELATED APPLICATION(S

This application claims benefit of priority to Korean Patent Application No. 10-2025-0010485 filed on January 23, 2025 in the Korean Intellectual Property Office, the disclosure of which is herein incorporated by reference in its entirety.

### BACKGROUND

The present inventive concept relates to a semiconductor processing apparatus.

A semiconductor process may include a photolithography process, an etching process, a deposition process, etc. for forming a plurality of layers on a substrate such as a wafer or the like, and a plurality of patterns may be formed on each of the plurality of layers. Prior to performing the photolithography process, a process of applying a photoresist on the wafer to form a photoresist layer may be performed. A semiconductor processing apparatus for forming the photoresist layer on the wafer may include a spin coating unit rotating the wafer to form the photoresist layer, a storage container storing the photoresist, a supply device supplying the photoresist stored in the storage container to the spin coating unit, etc. In order to increase process efficiency, one semiconductor processing apparatus may include a plurality of spin coating units and a plurality of supply devices, but routing a plurality of pipes, a plurality of cables, or the like for connecting the spin coating units and the supply devices in the semiconductor processing apparatus may become very complicated and difficult.

### SUMMARY

An aspect of the present inventive concept is to provide a semiconductor processing apparatus capable of easily disposing pipes and cables in a narrower space by reducing the number of cables included in a supply control unit supplying a photoresist to a spin coating unit applying the photoresist to a wafer.

According to an aspect of the present disclosure, a semiconductor processing apparatus includes a storage container configured to store a photoresist, a supply control unit including a plurality of pump devices drawing the photoresist from the storage container, at least one pump controller controlling the plurality of pump devices, a system substrate to which the plurality of pump devices and the at least one pump controller are connected, wherein the system substrate extends lengthwise in a first direction, and a bulkhead structure defining a first space and a second space separated from each other, wherein the plurality of pump devices that are connected to the system substrate are disposed in the first space and the at least one pump controller that is connected to the system substrate is disposed in the second space adjacent to the first space in the first direction, and a spin coating unit including a stage on which a wafer is disposed, and a nozzle discharging the photoresist supplied by the plurality of pump devices onto the wafer. The system substrate includes a first surface, and a second surface opposing the first surface, each of the first surface and the second surface extending lengthwise in the first direction, a plurality of first connectors directly connected to a first group of pump devices of the plurality of pump devices, the first group of pump devices being disposed on the first surface, and a plurality of second connectors directly connected to a second group of pump devices of the plurality of pump devices, the second group of pump devices being disposed on the second surface. Each first connector of the plurality of first connectors and each second connector of the plurality of second connectors are arranged alternately in the first direction.

According to an aspect of the present disclosure, a semiconductor processing apparatus includes a storage container configured to store a photoresist, a supply control unit including a plurality of pump devices drawing the photoresist from the storage container, at least one pump controller controlling the plurality of pump devices, and a system substrate to which the plurality of pump devices and the at least one pump controller are connected, and a spin coating unit including a stage on which a wafer is disposed, and a nozzle discharging the photoresist supplied by the plurality of pump devices onto the wafer. The system substrate includes a first surface, and a second surface opposing the first surface. Each of the first surface and the second surface extends lengthwise in a first direction. A first group of pump devices among the plurality of pump devices are coupled to the first surface. A second group of pump devices among the plurality of pump devices are coupled to the second surface. The first group of pump devices are arranged in the first direction. The second group of pump devices are arranged in the first direction. Each pump device of the first group of pump devices and a corresponding device of the second group of pump devices are positioned at a same location in the first direction.

According to an aspect of the present disclosure, a semiconductor processing apparatus includes a storage container configured to store a photoresist, a supply control unit including a plurality of pump devices drawing the photoresist from the storage container, at least one pump controller controlling the plurality of pump devices, and a system substrate to which the plurality of pump devices and the at least one pump controller are connected, and a spin coating unit including a stage on which a wafer is disposed, and a nozzle discharging the photoresist supplied by the plurality of pump devices onto the wafer. The system substrate includes a bulkhead structure defining a first space and a second space separated from each other. The system substrate extends lengthwise in a first direction. The plurality of pump devices are disposed in the first space and the at least one pump controller is disposed in the second space adjacent to the first space in the first direction. Each of the plurality of pump devices includes a tank in which the photoresist is stored, a step motor installed in an explosion-proof space separated from the tank, and a pump housing in which the tank and the step motor are accommodated and including the explosion-proof space. The pump housing includes a pair of surfaces opposing each other in a second direction perpendicular to the first direction, and at least one air hole disposed on each surface of the pair of surfaces and configured to pass a cooling gas through the explosion-proof space.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a view illustrating a semiconductor processing apparatus according to an embodiment.

FIGS. 2 and 3 are views illustrating a semiconductor processing apparatus according to an embodiment.

FIGS. 4, 5, and 6 are views illustrating a system substrate included in a supply control unit in a semiconductor processing apparatus according to an embodiment.

FIGS. 7 and 8 are views illustrating a supply control unit included in a semiconductor processing apparatus according to an embodiment.

FIGS. 9, 10, and 11 are views illustrating a cooling method of a supply control unit included in a semiconductor processing apparatus according to an embodiment.

FIGS. 12, 13, 14, and 15 are views illustrating a pump device included in a semiconductor processing apparatus according to an embodiment.

FIG. 16 is a view illustrating a supply control unit included in a semiconductor processing apparatus according to an embodiment.

### DETAILED DESCRIPTION

Hereinafter, various embodiments will be described with reference to the attached drawings.

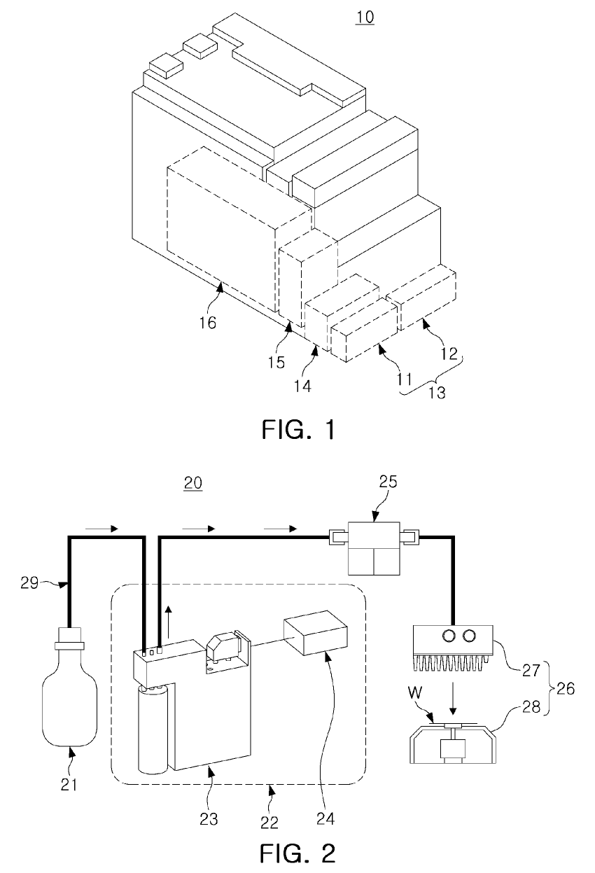

FIG. 1 is a view illustrating a semiconductor processing apparatus according to an embodiment.

A semiconductor processing apparatus 10 according to an embodiment may be a spinner device that forms a photoresist (PR) layer on a wafer by discharging a photoresist while rotating the wafer. The spinner device may be disposed in a semiconductor process line, together with an exposure device that performs a photolithography process by irradiating light of a predetermined wavelength band onto the photoresist layer. For example, while discharging the photoresist onto the wafer, a rate of rotating the wafer may be changed over time, and a bake process may be further performed to heat the wafer after the photoresist is discharged or coated on the wafer.

Referring to FIG. 1, a semiconductor processing apparatus 10 according to an embodiment may include a storage container 13 (11 and 12), a supply control unit 14, a PR supply unit 15, and a spin coating unit 16. A photoresist may be stored in the storage container 13. The photoresist stored in the storage container 13 may be drawn out by the supply control unit 14, and may be then supplied to the spin coating unit 16 through the PR supply unit 15.

The supply control unit 14 may include a plurality of pump devices sucking the photoresist using pressure, and at least one pump controller controlling the plurality of pump devices. In response to control of the pump controller, the plurality of pump devices may draw the photoresist out from the storage container 13, and the drawn photoresist may be temporarily stored in each of the plurality of pump devices.

The PR supply unit 15 may include a dispenser valve, a flow meter, or the like. The flow meter may monitor an amount of photoresist supplied to the spin coating unit 16. A main controller of the semiconductor processing apparatus 10 may control the dispenser valve with reference to monitored results of the flow meter to adjust the amount of photoresist supplied to the spin coating unit 16.

The spin coating unit 16 may include a stage on which a target object to which the photoresist is to be applied, such as a wafer, a mother substrate for display, or the like is disposed. The spin coating unit 16 may further include a nozzle located on the stage and discharging the photoresist. For example, one semiconductor processing apparatus 10 may include a plurality of spin coating units, and the plurality of spin coating units may simultaneously perform a process of forming a photoresist layer on a plurality of wafers using the photoresist supplied from the supply control unit 14.

The storage container 13, the supply control unit 14, the PR supply unit 15, the spin coating unit 16, and the like, included in the semiconductor processing apparatus 10 may be electrically connected to the main controller for control, and may be connected with each other through a pipe providing a transmission path for the photoresist. Therefore, cables for electrical connection and pipes for supplying the photoresist may be disposed in a complex manner in an internal space of the semiconductor processing apparatus 10, which may make it difficult to implement the semiconductor processing apparatus 10.

According to an embodiment, to increase efficiency of the semiconductor process, one semiconductor processing apparatus 10 may include a plurality of spin coating units, a plurality of supply control units, and a plurality of storage containers. In this case, the number of cables and the number of pipes may inevitably increase, and difficulty of arranging and connecting the cables and the pipes in the semiconductor processing apparatus 10 may further increase. In addition, cables electrically connecting the plurality of pump devices and the plurality of pump controllers in the supply control unit 14, and pipes connecting the plurality of pump devices to the storage container 13 and the PR supply unit 15 may all be routed. Although cables and pipes may be easily disposed by increasing a size of the supply control unit 14, there may be bound to be a limit to increasing the size of the supply control unit 14 due to characteristics of the semiconductor processing apparatus 10 that should be designed to be disposed in a limited space. For example, while increasing the size of the supply control unit 14 may facilitate easier routing of cables and pipes, the overall size of the supply control unit 14 is inherently limited by the spatial constraints of the semiconductor processing apparatus 10, which are to be designed to fit within a confined installation area.

In an embodiment, a semiconductor processing apparatus 10 that may more simply dispose cables and pipes is proposed. In a semiconductor processing apparatus 10 according to an embodiment, cables for electrically connecting a plurality of pump devices and a plurality of pump controllers in a supply control unit 14 may be omitted, and a system substrate on which wiring patterns are implemented may be used to electrically connect a plurality of pump devices and a plurality of pump controllers to each other. Therefore, most of cables required for electrical connection between a plurality of pump devices and a plurality of pump controller may be omitted, and the supply control unit 14 and the semiconductor processing apparatus 10 including the same may be implemented in a limited space.

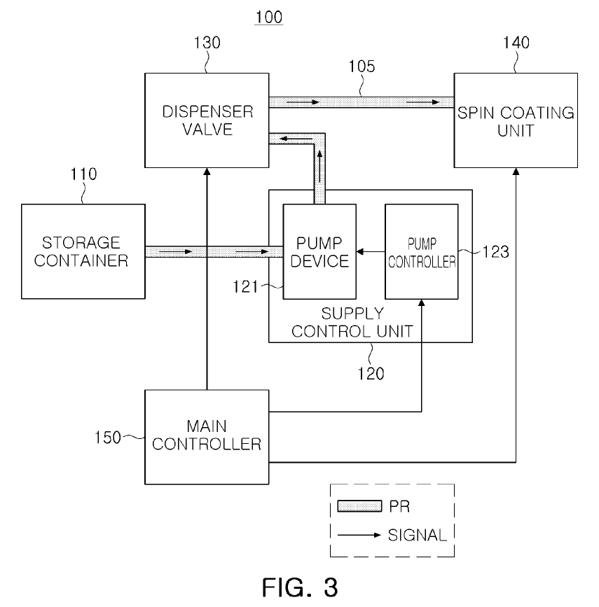

FIGS. 2 and 3 are views illustrating a semiconductor processing apparatus according to an embodiment.

First, referring to FIG. 2, a semiconductor processing apparatus 20 according to an embodiment may include a storage container 21, a supply control unit 22, a dispenser valve 25, a spin coating unit 26, and the like. FIG. 2 is a view illustrating the semiconductor processing apparatus 20. Although each of the components—such as the storage container 21, the supply control unit 22, the dispenser valve 25, and the spin coating unit 26—is illustrated as a single element for simplicity, it is to be understood that one or more of these components may be provided in plural.

The photoresist may be stored in the storage container 21, and the storage container 21 may be connected to a pump device 23 of the supply control unit 22 through a PR pipe 29. When the pump device 23 operates, the photoresist may move to the pump device 23 through the PR pipe 29 from the storage container 21, and the pump device 23 may provide the photoresist to the dispenser valve 25. By opening and closing operations of the dispenser valve 25, the photoresist may be supplied to a nozzle 27 of the spin coating unit 26, and the nozzle 27 may supply the photoresist to a wafer W disposed on a stage 28. For example, the nozzle 27 may discharge the photoresist while the wafer W disposed on the stage 28 rotates.

An operation of the pump device 23 may be controlled by a pump controller 24 of the supply control unit 22. Therefore, an electrical connection path should be provided between the pump device 23 and the pump controller 24, and as a result, in the supply control unit 22, the electrical connection path between the pump device 23 and the pump controller 24 may be implemented together, in addition to the PR pipe 29. Depending on an embodiment, a single supply control unit 22 may include a plurality of pump devices 23, and therefore, when the pump device 23 and the pump controller 24 are electrically connected using separate cables, a plurality of cables and a plurality of PR pipes 29 may be disposed in the supply control unit 22. The increase of the plurality of pump devices 23 in the supply control unit 22 may increase difficulty of implementing the supply control unit 22 and also difficulties in terms of maintenance/repair.

In an embodiment, the problem may be solved by using a system substrate including wiring patterns and connectors. The system substrate may include connectors to which the pump device 23 and the pump controller 24 are connected, and wiring patterns electrically connecting the connectors. By omitting most of the cables for electrically connecting the pump device 23 and the pump controller 24, a space for disposing the PR pipe 29 connected to the pump device 23 may be sufficiently secured. Therefore, difficulty in implementing the supply control unit 22 may be significantly reduced, and convenience of maintenance/repair of the semiconductor processing apparatus 20 may also be improved.

FIG. 3 may be a block diagram illustrating a semiconductor processing apparatus 100 according to an embodiment. Referring to FIG. 3, a semiconductor processing apparatus 100 according to an embodiment may include a storage container 110, a supply control unit 120, a dispenser valve 130, a spin coating unit 140, a main controller 150, and the like. The supply control unit 120 may include a pump device 121 and a pump controller 123.

Operations of the storage container 110, the supply control unit 120, the dispenser valve 130, and the spin coating unit 140 may be controlled by the main controller 150. A PR pipe 105 supplying a photoresist from the storage container 110 to the spin coating unit 140 through the pump device 121 and the dispenser valve 130 may be included in the semiconductor processing apparatus 100.

The main controller 150 may monitor an amount of the photoresist stored in the storage container 110, and the pump controller 123 of the supply control unit 120 may control the pump device 121 in response to control from the main controller 150. For example, the pump controller 123 may control the pump device 121 to suck the photoresist stored in the storage container 110. The photoresist drawn out by the pump device 121 may be supplied to the spin coating unit 140 through the dispenser valve 130, and the photoresist may be discharged onto a wafer seated on a stage of the spin coating unit 140.

In a semiconductor processing apparatus 100 according to an embodiment, the pump device 121 and the pump controller 123 may be coupled to a single system substrate. The system substrate may include connectors connected to the pump device 121 and the pump controller 123, and wiring patterns electrically connecting the connectors to each other. According to an embodiment, connectors may be disposed on a first surface and a second surface of the system substrate opposing each other, and thus, a plurality of pump devices 121 and a plurality of pump controllers 123 may be coupled to both surfaces of the system substrate. For example, the plurality of pump devices 121 may include a first group of pump devices which are directly connected to connectors formed at the first surface of the system substrate, and a second group of pump devices which are directly connected to connectors formed at the second surface of the system substrate. The plurality of pump controllers 123 may include a first group of pump controllers which are directly connected to control connectors formed at the first surface of the system substrate, and a second group of pump controllers which are directly connected to control connectors formed at the second surface of the system substrate. By electrically connecting the pump devices 121 and the pump controllers 123 to each other using the system substrate, most of the cables electrically connecting the pump devices 121 and the pump controllers 123 may be omitted, and a space of disposing the PR pipe 105 in the supply control unit 120 may be sufficiently secured. A region to which the pump devices 121 are connected in the system substrate may be distinguished from a region to which the pump controllers 123 are connected in the system substrate, and a bulkhead structure may be installed between the two regions according to an embodiment. By the bulkhead structure, cooling air introduced from the outside may flow in both upward and downward directions of the pump device 121, and cooling efficiency of the semiconductor processing apparatus 10 may be improved. In an embodiment, each pump controller 123 may control a corresponding pump device among the pump devices 121. The present disclosure is not limited thereto. In an embodiment, each pump controller 123 may control at least two or more pump devices among the pump devices 121.

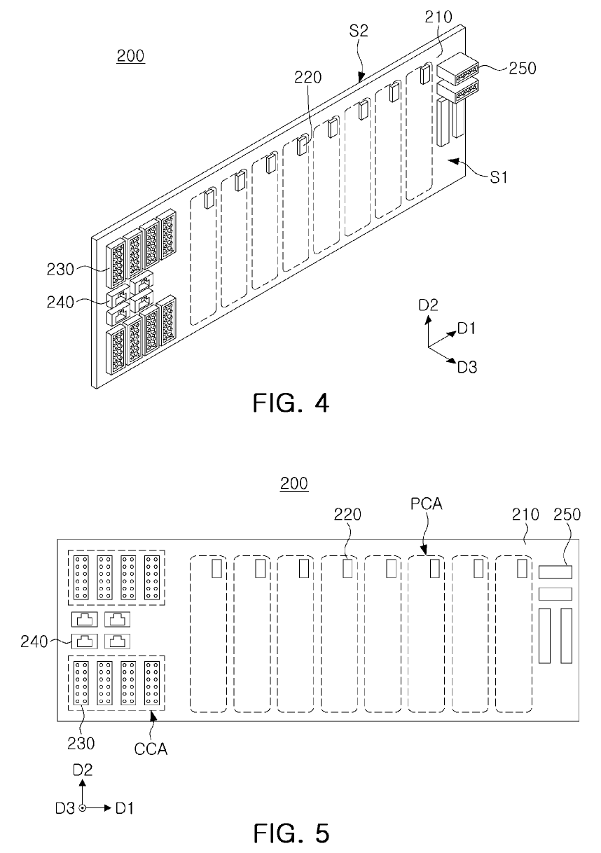

FIGS. 4 to 6 are views illustrating a system substrate included in a supply control unit in a semiconductor processing apparatus according to an embodiment.

Referring to FIG. 4, a system substrate 200 included in a supply control unit in a semiconductor processing apparatus according to an embodiment may include a substrate body 210, a plurality of connectors 220, a plurality of control connectors 230, a plurality of communication connectors 240, a plurality of external connectors 250, and the like. The plurality of connectors 220 may be connectors providing connection between the system substrate 200 and a plurality of pump devices, and the plurality of control connectors 230 may be connectors providing connection between the system substrate 200 and a plurality of pump controllers.

In the embodiment illustrated in FIG. 4, the plurality of connectors 220 may be disposed in a first direction D1. Therefore, a plurality of pump devices connected to the system substrate 200 may also be disposed in the first direction D1. The system substrate 200 may include a first surface S1 and a second surface S2, parallel to the first direction D1 and a second direction D2 and opposing each other in a third direction D3, and the plurality of connectors 220 and the plurality of control connectors 230 may be disposed on each of the first surface S1 and the second surface S2. Therefore, a plurality of pump devices coupled to the system substrate 200 may be disposed in the first direction D1 and the third direction D3 (i.e., on the first surface S1 and the second surface S2). In an embodiment, the second direction D2 may be perpendicular to a floor on which the semiconductor processing apparatus 10 is installed, and the first and third directions D1 and D3 may be parallel to the floor.

The system substrate 200 may include a plurality of wiring patterns disposed in the substrate body 210, and the plurality of connectors 220 and the plurality of control connectors 230 may be electrically connected to each other by the plurality of wiring patterns. Therefore, electrical connection of a plurality of pump devices and a plurality of pump controllers included in a supply control unit may be implemented only with a system substrate without cables exposed to the outside for electrical connection. For the brevity of illustration, a detailed connection between the plurality of pump devices and the plurality of pump controllers are omitted. Depending on how many pump devices are controlled by each pump controller, connections or routing of the wiring patterns may be variously formed in the system substrate 200. In an embodiment, the system substrate 200 may be a single-layer printed circuit board (PCB) or a multilayer PCB. In an embodiment, the wiring patterns may be disposed on a surface of the PCB in a single-layered PCB or disposed in a multi-layered pattern in the multilayer PCB. In an embodiment, a material of the wiring patterns may be copper.

The plurality of communication connectors 240 may have a structure that may be coupled to a communication cable. In the system substrate 200 according to an embodiment illustrated in FIG. 4, the plurality of communication connectors 240 may be located between the plurality of control connectors 230 in the second direction D2. However, the present invention is not limited thereto, and positions and/or the number of the plurality of communication connectors 240 may be variously modified according to embodiments.

The plurality of external connectors 250 may connect the system substrate 200 to other components included in the semiconductor processing apparatus. For example, the system substrate 200 may be connected to a power supply device through the plurality of external connectors 250, and may be supplied with power required for operations of the plurality of pump devices and the plurality of pump controllers. In an embodiment, the system substrate 200 may be connected to a main controller of the semiconductor processing apparatus through the plurality of external connectors 250. For example, the external connectors 250 of the system substrate 200 may be electrically connected to the main controller 150 of FIG. 3 using a cable.

Referring to FIG. 5 together with FIG. 4, a plurality of pump connection areas PCA to which the plurality of pump devices are connected, and a plurality of controller connection areas CCA to which the plurality of pump controllers are connected may be defined on the first surface S1 of the system substrate 200. The plurality of pump connection areas PCA and the plurality of controller connection areas CCA may also be defined on the second surface S2 opposing the first surface S1 in the third direction D3.

On the first surface S1 of the system substrate 200, the plurality of pump connection areas PCA may be disposed in the first direction D1, and the plurality of controller connection areas CCA may be disposed in the second direction D2. However, the number and arrangement of the plurality of pump connection areas PCA and the plurality of controller connection areas CCA may be changed depending on embodiments. The plurality of external connectors 250 for connecting an external device and the system substrate 200 may be located close to one end of the system substrate 200 in the first direction D1.

In an embodiment illustrated in FIGS. 4 and 5, 16 pump devices and 4 pump controllers are coupled to one system substrate 200. One pump controller may control 4 pump devices. For example, 8 pump devices and 2 pump controllers may be directly connected to eight connectors 220 and two control connectors 230 on a first surface of the system substrate 200, and the other eight pump devices and the other two pump controllers may be directly connected to eight connectors 220 and two control connectors 230 on a second surface, opposing the first surface in the third direction D3, of the system substrate 200. The present disclosure is not limited thereto. In an embodiment, any number of pump devices and any number of pump controllers may be connected with each other using the system substrate 200.

Each of the plurality of connectors 220 may provide not only an electrical connection between the plurality of pump devices and the plurality of pump controllers, but also a physical connection between the system substrate 200 and the plurality of pump devices. For example, the plurality of pump devices may be coupled to the system substrate 200 while being connected to each of the plurality of connectors 220. In an embodiment, each of the plurality of connectors 220 may be implemented as a dip-type connector such that the plurality of connectors 220 may provide sufficient support for the plurality of pump devices.

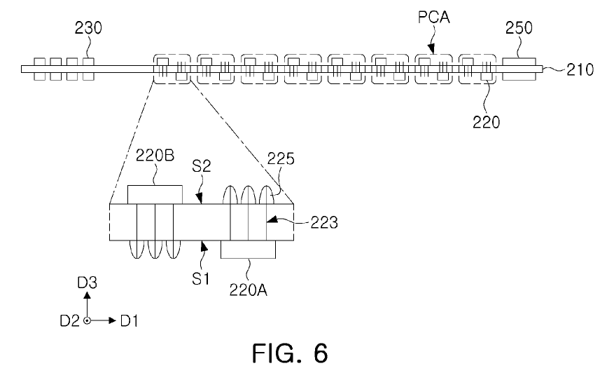

Referring to FIG. 6, the plurality of connectors 220 may include a plurality of first connectors 220A connected to the pump devices on the first surface S1 of the substrate body 210, and a plurality of second connectors 220B connected to the pump devices on the second surface S2 of the substrate body 210. The plurality of first connectors 220A and the plurality of second connectors 220B may include a plurality of pins 223 penetrating the substrate body 210, and the plurality of pins 223 may be fixed by a fixing portion 225 on a surface of the substrate body 210, opposite thereto. For example, each of the plurality of connectors may be a dip-type connector including the plurality of pins 223 penetrating the substrate body 210 of the system substrate 200.

For example, the plurality of first connectors 220A may be coupled to the pump devices on the first surface S1, and the plurality of pins included in each of the plurality of first connectors 220A may be coupled to the fixing portion 225 on the second surface S2. For example, each of the plurality of first connectors 220A at the first surface S1 may be directly connected to a corresponding pump device, on the first surface S1, of the plurality of pump devices. Similarly, the plurality of second connectors 220B may be coupled to the pump devices on the second surface S2, and the plurality of pins included in each of the plurality of second connectors 220B may be coupled to the fixing portion 225 on the first surface S1. For example, each of the plurality of second connectors 220B at the second surface S2 may be directly connected to a corresponding pump device, on the second surface S2, of the plurality of pump devices.

Since each of the plurality of connectors 220 is implemented as a deep-type connector including the plurality of pins 223 penetrating the substrate body 210, the plurality of first connectors 220A and the plurality of second connectors 220B may not be disposed in the same position in the first direction D1. For example, the system substrate 200 may not be implemented in a form in which the plurality of first connectors 220A and the plurality of second connectors 220B oppose each other in the third direction D3. In an embodiment, the plurality of first connectors 220A and the plurality of second connectors 220B are disposed in different positions in the first direction D1. Therefore, as illustrated in FIG. 6, each of the plurality of first connectors 220A and each of the plurality of second connectors 220B may be alternately disposed in the first direction D1.

In each of the plurality of pump connection areas PCA, the first connector 220A and the second connector 220B may be disposed in different positions in the first direction D1. Referring to FIG. 6, in each of the plurality of pump connection areas PCA, in the first direction D1, the first connector 220A may be located closer to the plurality of external connectors 250 than the plurality of control connectors 230, and the second connector 220B may be located closer to the plurality of control connectors 230 than the plurality of external connectors 250. For example, the first connector 220A and the second connector 220B in each of the plurality of pump connection areas PCA may not be aligned in a central portion in the first direction D1.

Arrangement of the plurality of pump devices connected to the system substrate 200 may be changed depending on a position of the pump connector connected to the connector 220 in each of the plurality of pump devices. For example, when the pump connector in each of the plurality of pump devices is aligned in a central portion, the plurality of pump devices connected to the system substrate 200 may be disposed in a zigzag manner in the first direction D1. When the pump connector in each of the plurality of pump devices is disposed in a position shifted to one side, the plurality of pump devices connected to the system substrate 200 may be disposed in a structure opposing each other in the third direction D3 with the substrate body 210 interposed therebetween.

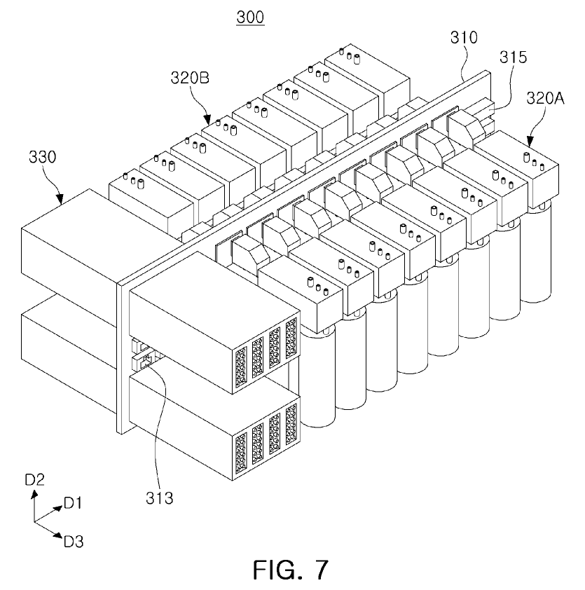

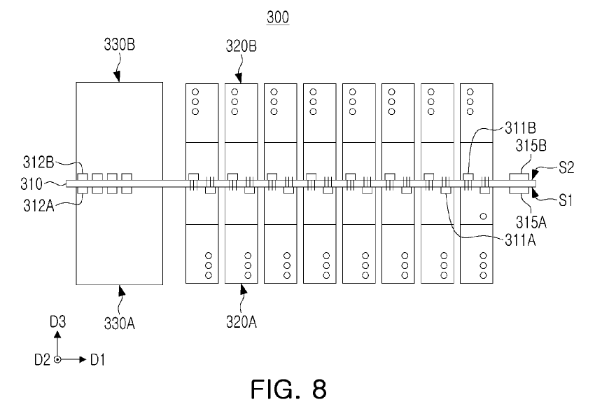

FIGS. 7 and 8 are views illustrating a supply control unit included in a semiconductor processing apparatus according to an embodiment.

Referring to FIGS. 7 and 8, a supply control unit 300 according to an embodiment may include a system substrate 310, a plurality of pump devices 320A and 320B, a plurality of pump controllers 330, and the like. In an embodiment described with reference to FIGS. 7 and 8, the system substrate 310 may have a structure similar to the embodiment described with reference to FIGS. 4 to 6 above. For example, the system substrate 310 may include a substrate body having a first surface S1 and a second surface S2, a plurality of connectors 311A and 311B, a plurality of control connectors 312A and 312B, a plurality of communication connectors 313, a plurality of external connectors 315A and 315B, and the like.

The first surface S1 and the second surface S2 in the substrate body may be a pair of surfaces parallel to the first direction D1 and the second direction D2 and opposing each other in the third direction D3. A plurality of first connectors 311A and a plurality of first control connectors 312A may be disposed on the first surface S1, and a plurality of second connectors 311B and a plurality of second control connectors 312B may be disposed on the second surface S2.

As described above with reference to FIGS. 4 to 6, each of the plurality of connectors 311A and 311B connected to the plurality of pump devices 320A and 320B may be implemented as a deep-type connector. Therefore, as illustrated in FIG. 8, the first connectors 311A and the second connectors 311B may not be disposed to oppose each other in the third direction D3, and the first connectors 311A and the second connectors 311B may be disposed in different positions in the first direction D1.

The plurality of pump devices 320A and 320B may include first pump devices 320A coupled to the system substrate 310 on the first surface S1 and directly connected to the first connectors 311A, and second pump devices 320B coupled to the system substrate 310 on the second surface S2 and directly connected to the second connectors 311B. In an embodiment described with reference to FIGS. 7 and 8, a pump connector included in each of the plurality of pump devices 320A and 320B and connected to one of the plurality of connectors 311A and 311B may be disposed in a position not aligned in a central portion in the first direction D1. For example, the pump connector of each pump device may be closer to one side of each pump device so that a pair of pump devices arranged in the third direction are positioned on at the same location in the first direction D1. The pair of pump devices are one pump device 320A and one pump device 320B which are positioned at the same location in the first direction D1.

Therefore, positions in which the first pump devices 320A are coupled to the first surface S1 in the first direction D1 may be the same as positions in which the second pump devices 320B are coupled to the second surface S2 in the first direction D1. The first pump devices 320A and the second pump devices 320B may be disposed to oppose each other in the third direction D3, and one first pump device 320A may be disposed in the same position as one second pump device 320B in the first direction D1. For example, a pair of pump devices 320A and 320B that are arranged in the third direct D3 may be in the same location in the first direction D1 and the second direction D2.

Referring to the first pump device 320A and the second pump device 320B, disposed in the same position in the first direction D1 and opposing each other in the third direction D3, the first pump device 320A and the second pump device 320B may be coupled to the system substrate 310 in a state rotated 180 degrees clockwise in a plane, parallel to the first direction D1 and the third direction D3. Therefore, without having to manufacture the first pump device 320A and the second pump device 320B with different structures, one pump device having the same structure may be applied to both the first pump device 320A and the second pump device 320B. For example, a configuration of the first pump device 320A may be identical to a configuration of the second pump device 320B. In other words, the first pump device 320A may be identical to the second pump device 320B, and thus the first pump device 320A may be directly connected to one of the connectors 311A and 311B, and the second pump device 320B may be directly connected to one of the connectors 311A and 311B.

Each of the plurality of pump devices 320A and 320B may include a front surface and a rear surface, parallel to the second direction D2 and the third direction D3 and opposing each other in the first direction D1. Referring to FIGS. 7 and 8, the front surface of each of the first pump devices 320A may be located in the same position as the rear surface of each of the second pump devices 320B in the first direction D1. In this manner, by arranging the first pump devices 320A and the second pump devices 320B in the same position in the first direction D1, as many pump devices 320A and 320B as possible may be disposed in a limited space provided by the supply control unit 300. With the arrangement of the pump devices 320A in the rotated manner as described above, the first pump devices 320A and the second pump devices 320B may be positioned at the same location in the first direction D1, and a greater number of pump devices 320A and 320B can be accommodated within the limited space available in the supply control unit 300. In an embodiment, the system substrate 310 may extend lengthwise in the first direction D1, and the first and second surfaces S1 and S2 may be opposing in the third direction D3.

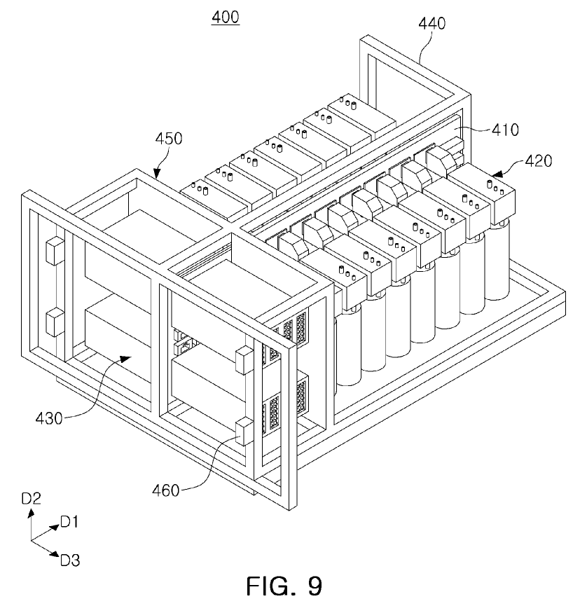

FIGS. 9 to 11 are views illustrating a cooling method of a supply control unit included in a semiconductor processing apparatus according to an embodiment.

As described above, a supply control unit 400 may be a device drawing a photoresist stored in a storage container out and supplying the same to a spin coating unit rotating a wafer and applying the photoresist. Referring to FIGS. 9 to 11, the supply control unit 400 may include a system substrate 410, a plurality of pump devices 420, a plurality of pump controllers 430, a housing 440, a bulkhead structure 450, a plurality of cooling fans 460, and the like.

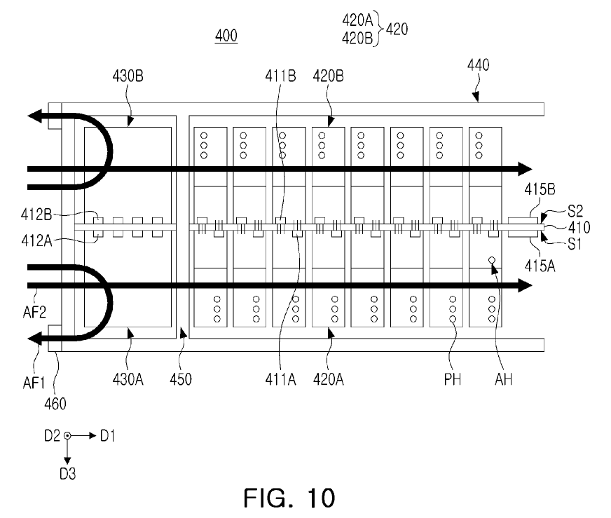

The system substrate 410 may be coupled to the plurality of pump devices 420 and the plurality of pump controllers 430. Referring to FIG. 10, the system substrate 410 may have a first surface S1 and a second surface S2, opposing each other in the third direction D3, and a plurality of first connectors 411A and a plurality of first control connectors 412A may be disposed on the first surface S1, and a plurality of second connectors 411B and a plurality of second control connectors 412B may be disposed on the second surface S2. A plurality of first pump devices 420A may be connected to the plurality of first connectors 411A, and a plurality of second pump devices 420B may be connected to the plurality of second connectors 411B. A plurality of pump controllers 430A and 430B may be connected to the plurality of control connectors 412A and 412B.

A coupled structure of the system substrate 410, the plurality of pump devices 420, and the plurality of pump controllers 430 may be similar to that described above with reference to FIGS. 7 and 8. For example, positions in which the plurality of first connectors 411A are disposed on the first surface S1 may be different from positions in which the plurality of second connectors 411B are disposed on the second surface S2. This may be because each of the plurality of connectors 411A and 411B may be a deep-type connector.

Positions in which the plurality of first pump devices 420A are disposed on the first surface S1 may be the same as positions in which the plurality of second pump devices 420B are disposed on the second surface S2. In order for the plurality of first pump devices 420A and the plurality of second pump devices 420B to be located in the same positions while opposing each other, pump connectors of each of the plurality of pump devices 420 may not be aligned in a central portion, and may be shifted to one side of each pump device in the first direction D1. In addition, when comparing the first pump device 420A and the second pump device 420B, the second pump device 420B may be coupled to the system substrate 410 in a form in which the first pump device 420A rotates 180 degrees clockwise or counterclockwise in a plane, perpendicular to the second direction D2. Therefore, the plurality of pump devices 420 may be configured with only one pump device having the same structure.

The system substrate 410, the plurality of pump devices 420, and the plurality of pump controllers 430, and the like may be installed in the housing 440. Heat generated during an operation of the supply control unit 400 may be managed or dissipated by air cooling. For example, in order to increase heat dissipation efficiency of the supply control unit 400, a heat dissipation plate may be installed on the outside of the housing 440, and the plurality of cooling fans 460 may be installed in regions adjacent to the plurality of pump controllers 430. The plurality of cooling fans 460 may suck in external air to improve cooling efficiency of the supply control unit 400.

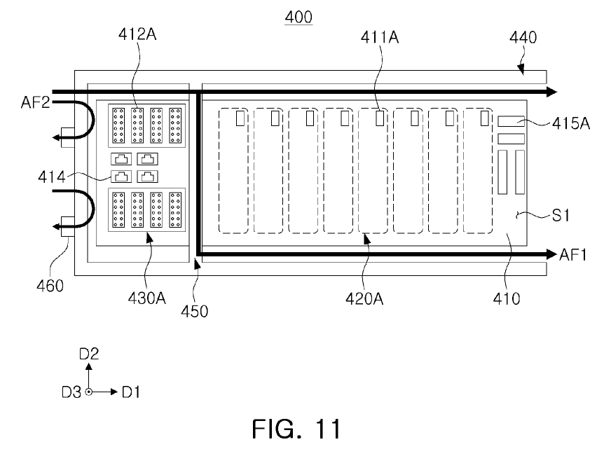

Referring to FIGS. 10 and 11, air flows AF1 and AF2 for managing the heat generated during the operation of the supply control unit 400 by air cooling may be illustrated. Referring to FIGS. 10 and 11, a first air flow AF1 in which air introduced from a rear end of the supply control unit 400 passes through the plurality of pump controllers 430 and the plurality of pump devices 420 and is discharged to a front end of the supply control unit 400, may be formed. The rear end of the supply control unit 400 may be defined as one end in which the plurality of pump controllers 430 and a plurality of communication connectors 414 are disposed, and the front end of the supply control unit 400 may be defined as one end in which a plurality of external connectors 415A and 415B are disposed. A second air flow AF2 in which air is introduced into each of the plurality of pump controllers 430 from the outside and then discharged again through the plurality of cooling fans 460, may be generated. According to an embodiment, a heat dissipation plate may be attached to one surface exposed from the rear end of the supply control unit 400 in each of the plurality of pump controllers 430.

As illustrated in FIGS. 10 and 11, a supply control unit 400 according to an embodiment may include the bulkhead structure 450 that divides a region in which the plurality of pump devices 420 are disposed and a region in which the plurality of pump controllers 430 are disposed. In an embodiment, the bulkhead structure 450 may be formed integrally with the housing 440, and may be parallel to the second direction D2 and the third direction D3. For example, the bulkhead structure 450 may include a plate extending in the second direction D2 and the third direction D3 to define the region in which the plurality of pump devices 420 are disposed and the region in which the plurality of pump controllers 430 are disposed. The bulkhead structure 450 may include a plurality of structures disposed on both sides with the system substrate 410 interposed therebetween in the second direction D2, or a through-slit may be formed in one bulkhead structure 450 penetrating the system substrate 410 in the first direction D1.

The bulkhead structure 450 may allow the first air flow AF1 to be generated above and below the plurality of pump devices 420. Referring to FIG. 11, the first air flow AF1 may be formed above an upper surface and below a lower surface of each of the plurality of pump devices 420 in the second direction D2. Therefore, the heat generated during the operation of the supply control unit 400 may be effectively released.

Each of the plurality of pump devices 420 adopted in the supply control unit 400 according to an embodiment may include a PR connection unit PH to which a PR pipe sucking and then discharging the photoresist, based on an operation of a corresponding pump, is connected, and an air hole AH sucking and passing air in the second direction D2. In FIG. 10, for the simplicity of illustration, only one pump device is illustrated to have the air hole AH. However, each pump device has an air hole along with the PR connection unit PH. A PR valve included in each of the plurality of pump devices 420 may be provided in plural, and for example, each of the plurality of pump devices 420 may further include a drain valve connected to a filter, in addition to the PR valve PV.

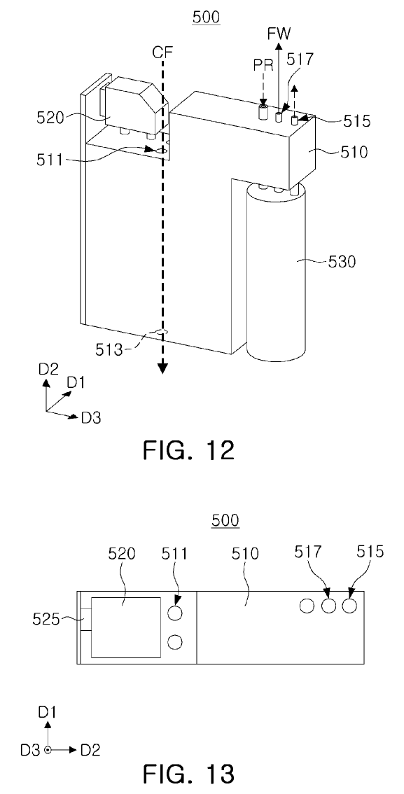

The air hole AH may be formed in upper and lower surfaces opposing each other in the second direction D2 of each of the plurality of pump devices 420, which will be discussed with refence to FIG. 12. A cooling gas, such as a nitrogen gas, an air, or the like, for cooling may be introduced into the air hole AH formed in one surface among the upper and lower surfaces, and the introduced cooling gas may be discharged through the air hole AH formed in the other surface among the upper and lower surfaces. Heat dissipation efficiency of a step motor included in each of the plurality of pump devices 420 may be improved by the cooling gas introduced into and discharged through the air hole AH.

FIGS. 12 to 15 are views illustrating a pump device included in a semiconductor processing apparatus according to an embodiment.

First, referring to FIG. 12, a pump device 500 according to an embodiment may include a pump housing 510, a communication unit 520 mediating connection between the pump device 500 and a system substrate, a filter unit 530, and the like. The pump device 500 may be coupled to the system substrate in the third direction D3, and two or more pump devices connected to one system substrate may be disposed in the first direction D1.

The pump housing 510 may include an upper surface and a lower surface, opposing each other, in the second direction D2, and a PR connection unit 515 may be provided on the upper surface. The PR connection unit 515 may be connected to a PR pipe connected to a storage container in which a photoresist PR is stored, and the PR pipe connected to a nozzle discharging the photoresist PR onto a wafer or the like. In addition to the PR connection unit 515, a discharge unit 517 may be further provided to discharge a waste FW accumulated in the filter unit 530 to the outside.

Air holes 511 and 513 may be formed in the upper and lower surfaces of the pump housing 510, respectively. In an embodiment illustrated in FIG. 12, a cooling gas CF may be introduced into an upper air hole 511 formed in the upper surface, and cooling gas CF may be discharged through a lower air hole 513 formed in the lower surface, but are not necessarily limited thereto.

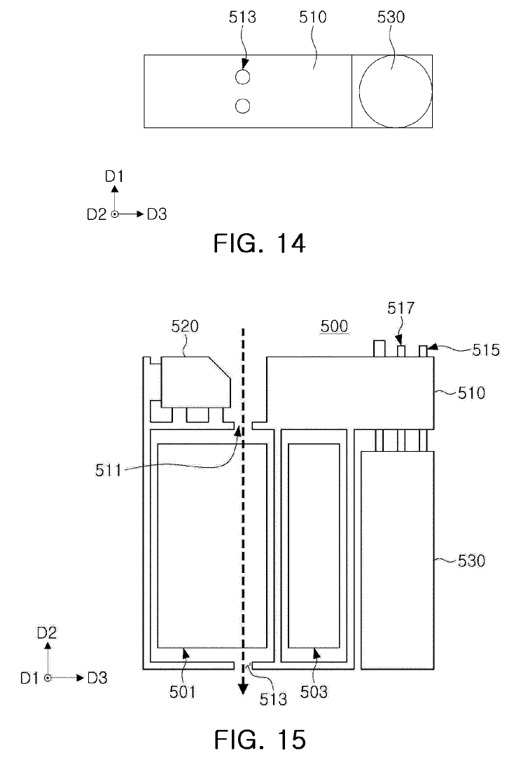

Inside the pump housing 510, a PR tank 503, as shown in FIG. 15, storing the photoresist PR sucked in from the storage container or the like, a step motor sucking the photoresist PR, or the like may be installed. To prevent damage caused by sparks or the like that may occur during an operation of the step motor, the step motor may be installed in an explosion-proof space separated from the PR tank. The air holes 511 and 513 formed in the upper and lower surfaces of the pump housing 510 may be formed in positions corresponding to the explosion-proof space in which the step motor is installed. Therefore, heat generated while the step motor is operating may be effectively managed by the cooling gas CF flowing through the air holes 511 and 513.

The step motor installed in the explosion-proof space may receive a control signal generated by a pump controller connected to the system substrate through the communication unit 520. To simplify an internal design of the pump housing 510, the explosion-proof space in which the step motor is installed may be located below the communication unit 520 in the second direction D2. For example, the PR tank 503 may be located between the explosion-proof space in which the step motor is installed and the filter unit 530 in the third direction D3. In addition, the pump device 500 may be coupled to the system substrate such that the step motor is located closer to the system substrate than the PR tank 503.

FIGS. 13 and 14 may be views illustrating upper and lower surfaces of a pump housing 510 included in a pump device 500. First, referring to FIG. 12, a PR connection unit 515 capable of sucking and discharging a photoresist PR and a discharge unit 517 discharging a waste CF generated in a filter unit 530 may be formed on an upper surface of a pump housing 510. As illustrated in FIGS. 13 and 14, each of the PR connection unit 515 and the discharge unit 517 may be formed on the filter unit 530 in the second direction D2. FIG. 13 shows a view when viewed from the top of the pump device 500, and FIG. 14 shows a view when viewed from the bottom of the pump device 500.

A communication unit 520 may be installed on the upper surface of the pump housing 510, and may include a corresponding connector 525 connecting to a connector of a system substrate. As described above, the corresponding connector 525 may be located in a position not aligned with a central portion of the communication unit 520 in the first direction D1 but may be shifted to one side of the communication unit 520.

Air holes 511 and 513 may be formed in the upper and lower surfaces of the pump housing 510, respectively. In an embodiment described with reference to FIGS. 13 and 14, a plurality of air holes 511 and 513 may be respectively formed on the upper and lower surfaces, and the number of air holes 511 and 513 may be changed depending on an embodiment. The air holes 511 and 513 may be formed in a position corresponding to an explosion-proof space in which a step motor is disposed in the pump housing 510, and a cooling gas for cooling heat emitted from the step motor while the pump device 500 is operating may be introduced through the air holes 511 and discharged through the air holes 513.

FIG. 15 may be a view illustrating a structure of a pump device 500. Referring to FIG. 15, a pump device 500 according to an embodiment may include a pump housing 510, a communication unit 520, a filter unit 530, and the like, and a driving unit 501 including a step motor and a PR tank 503 may be installed in the pump housing 510. A first internal space in which the driving unit 501 is installed and a second internal space in which the PR tank is installed may be physically separated from each other. The first internal space may be an explosion-proof space. Therefore, damage caused by sparks or the like that may occur during an operation of the driving unit 501 may be effectively prevented from affecting the PR tank.

Air holes 511 and 513 may be provided above and below the explosion-proof space in which the driving unit 501 is installed. For example, a cooling gas may flow from an upper air hole 511 disposed in an upper portion of the explosion-proof space to a lower air hole 513 disposed in a lower portion of the explosion-proof space. Therefore, heat generated from the driving unit 501 may be effectively cooled by the cooling gas.

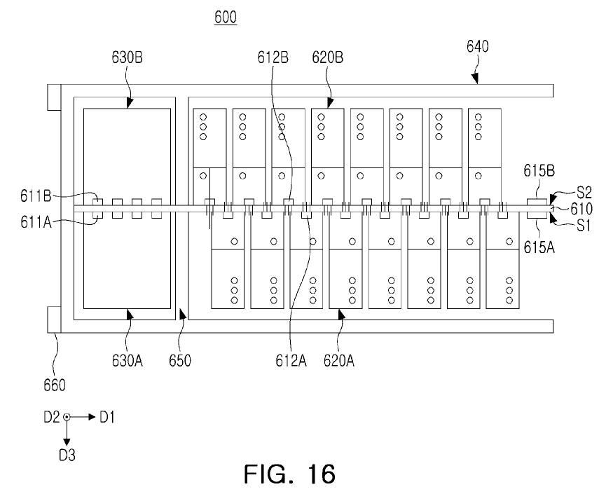

FIG. 16 is a view illustrating a supply control unit included in a semiconductor processing apparatus according to an embodiment.

A supply control unit 600 according to an embodiment illustrated in FIG. 16 may have a structure similar to the supply control unit 400 described with reference to FIGS. 9 and 10 above. For example, a system substrate 610, a plurality of pump devices 620A and 620B, and a plurality of pump controllers 630A and 630B may be installed in a space inside a housing 640. A space in which the plurality of pump devices 620A and 620B are installed and a space in which the plurality of pump controllers 630A and 630B are installed may be separated by a bulkhead structure 650 in the first direction D1.

By installing the bulkhead structure 650, cooling efficiency for cooling heat generated during an operation of the supply control unit 600 may be improved, as described above with reference to FIGS. 10 and 11. Air introduced from the outside by a plurality of cooling fans 660 may flow through the bulkhead structure 650 to lower portions of the plurality of pump devices 620A and 620B, and may then flow in the first direction D1. Therefore, the air flow may be formed in both upper and lower portions of the plurality of pump devices 620A and 620B in the second direction D2, such that cooling efficiency of the supply control unit 600 may be improved.

The system substrate 610 may include a plurality of connectors 611A and 611B connected to the plurality of pump devices 620A and 620B, a plurality of control connectors 612A and 612B connected to the plurality of pump controllers 630A and 630B, a plurality of external connectors 615A and 615B, and the like. In an embodiment illustrated in FIG. 16, the plurality of connectors 611A and 611B may be implemented as deep-type connectors.

In an embodiment illustrated in FIG. 16, first pump devices 620A coupled to a first surface S1 of the system substrate 610 and second pump devices 620B coupled to a second surface S2 of the system substrate 610 may be disposed in different positions in the first direction D1. For example, referring to FIG. 16, the first pump devices 620A and the second pump devices 620B may be disposed in a zigzag manner in the first direction D1. In each of the plurality of pump devices 620A and 620B, corresponding connectors connected to the plurality of connectors 611A and 611B may be aligned in a central portion in the first direction D1.

According to an embodiment, a supply control unit extracting a photoresist stored in a storage container and supplying the same to a spin coating unit may include a system substrate connected to a plurality of pump devices and at least one pump controller, and the plurality of pump devices and the pump controller may be electrically connected to each other through wiring patterns in the system substrate. Therefore, by omitting most of cables electrically connecting the plurality of pump devices and the pump controller, it is possible to sufficiently secure a space for disposing pipes connected to the plurality of pump devices. In addition, by disposing a bulkhead between the plurality of pump devices and the pump controller to secure a flow of cooling air in both directions of the plurality of pump devices, it is possible to effectively manage heat generated in the supply control unit during an operation.

Various advantages and effects of the present inventive concept are not limited to the above-described contents, and will be more easily understood in the process of explaining specific embodiments.

While example embodiments have been illustrated and described above, it will be apparent to those skilled in the art that modifications and variations could be made without departing from the scope of the present inventive concept as defined by the appended claims.

What is claimed is:

1. A semiconductor processing apparatus comprising:
a storage container configured to store a photoresist;
a supply control unit including:
a plurality of pump devices drawing the photoresist from the storage container,
at least one pump controller controlling the plurality of pump devices,
a system substrate to which the plurality of pump devices and the at least one pump controller are connected, wherein the system substrate extends lengthwise in a first direction, and
a bulkhead structure defining a first space and a second space separated from each other,
wherein the plurality of pump devices that are connected to the system substrate are disposed in the first space and the at least one pump controller that is connected to the system substrate is disposed in the second space adjacent to the first space in the first direction; and
a spin coating unit including a stage on which a wafer is disposed, and a nozzle discharging the photoresist supplied by the plurality of pump devices onto the wafer,
wherein the system substrate includes:
a first surface, and a second surface opposing the first surface, each of the first surface and the second surface extending lengthwise in the first direction,
a plurality of first connectors directly connected to a first group of pump devices of the plurality of pump devices, the first group of pump devices being disposed on the first surface, and
a plurality of second connectors directly connected to a second group of pump devices of the plurality of pump devices, the second group of pump devices being disposed on the second surface, and
wherein each first connector of the plurality of first connectors and each second connector of the plurality of second connectors are arranged alternately in the first direction.

2. The semiconductor processing apparatus of claim 1,
wherein each of the plurality of pump devices includes:
a tank in which the photoresist is stored,
a step motor installed in an explosion-proof space separated from the tank, and
a pump housing in which the tank and the step motor are accommodated and including the explosion-proof space, wherein the pump housing includes:
an upper surface and a lower surface opposing each other in a second direction, perpendicular to the first direction, and
at least one air hole disposed on the upper surface and the lower surface and connected to the explosion-proof space,
wherein the at least one air hole is configured to pass a cooling gas through the explosion-proof space, and
wherein the first surface of the system substrate and the second surface of the system substrate are opposing in a third direction perpendicular to the first direction and the second direction.

3. The semiconductor processing apparatus of claim 2,
wherein in each of the plurality of pump devices connected to the system substrate, the step motor is located closer to the system substrate than the tank in the third direction.

4. The semiconductor processing apparatus of claim 1,
wherein the supply control unit includes a plurality of pump controllers, and
wherein each pump controller of the plurality of pump controllers controls two or more pump devices among the plurality of pump devices.

5. The semiconductor processing apparatus of claim 4,
wherein the plurality of pump controllers are disposed in different positions in at least one of a second direction, perpendicular to the first direction and a third direction, perpendicular to the first direction and the second direction, and
wherein the first surface of the system substrate and the second surface of the system substrate are opposing in the third direction.

6. The semiconductor processing apparatus of claim 5,
wherein the plurality of pump controllers include a pair of pump controllers coupled to the system substrate, and
wherein the pair of pump controllers are disposed in a same position in the first direction and the second direction and oppose each other in the third direction.

7. The semiconductor processing apparatus of claim 5,
wherein the system substrate includes at least one communication connector disposed between portions of the plurality of pump controllers in the second direction.

8. The semiconductor processing apparatus of claim 1, further comprising:
a main controller controlling the storage container, the supply control unit, and the spin coating unit,
wherein the system substrate includes an external connector disposed on one end in the first direction and electrically connected to the main controller through a cable.

9. The semiconductor processing apparatus of claim 1,
wherein each of the plurality of first connectors and the plurality of second connectors is a dip-type connector including a plurality of pins penetrating a substrate body of the system substrate.

10. The semiconductor processing apparatus of claim 1,
wherein the at least one pump controller and the plurality of pump devices are electrically connected to each other by wiring patterns included in the system substrate, and
wherein the system substrate is a printed circuit board in which the wiring patterns are disposed.

11. A semiconductor processing apparatus comprising:
a storage container configured to store a photoresist;
a supply control unit including:
a plurality of pump devices drawing the photoresist from the storage container,
at least one pump controller controlling the plurality of pump devices, and
a system substrate to which the plurality of pump devices and the at least one pump controller are connected; and
a spin coating unit including a stage on which a wafer is disposed, and a nozzle discharging the photoresist supplied by the plurality of pump devices onto the wafer,
wherein the system substrate includes a first surface, and a second surface opposing the first surface,
wherein each of the first surface and the second surface extends lengthwise in a first direction,
wherein a first group of pump devices among the plurality of pump devices are coupled to the first surface,
wherein a second group of pump devices among the plurality of pump devices are coupled to the second surface,
wherein the first group of pump devices are arranged in the first direction,
wherein the second group of pump devices are arranged in the first direction, and
wherein each pump device of the first group of pump devices and a corresponding device of the second group of pump devices are positioned at a same location in the first direction.

12. The semiconductor processing apparatus of claim 11,
wherein a pump housing of each of the plurality of pump devices includes a front surface and a rear surface opposing each other in the first direction, and
wherein the front surface included in the pump housing of each pump device of the first group of pump devices is disposed in a position corresponding to the rear surface included in the pump housing of a corresponding pump device of the second group of pump devices in the first direction.

13. The semiconductor processing apparatus of claim 11,
wherein the system substrate includes a plurality of connectors coupled to the plurality of pump devices, and
wherein each of the plurality of connectors is a dip-type connector.

14. The semiconductor processing apparatus of claim 13,
wherein the plurality of connectors include:
a plurality of first connectors directly connected to the first group of pump devices, and
a plurality of second connectors directly connected to the second group of pump devices, and
wherein each first connector of the plurality of first connectors and each second connector of the plurality of second connectors are arranged alternately in the first direction.

15. The semiconductor processing apparatus of claim 11,
wherein a pump device in the first group of pump devices is identical to a pump device in the second group of pump devices.

16. A semiconductor processing apparatus comprising:
a storage container configured to store a photoresist;
a supply control unit including:
a plurality of pump devices drawing the photoresist from the storage container,
at least one pump controller controlling the plurality of pump devices, and
a system substrate to which the plurality of pump devices and the at least one pump controller are connected; and
a spin coating unit including:
a stage on which a wafer is disposed, and
a nozzle discharging the photoresist supplied by the plurality of pump devices onto the wafer,
wherein the system substrate includes a bulkhead structure defining a first space and a second space separated from each other,
wherein the system substrate extends lengthwise in a first direction,
wherein the plurality of pump devices are disposed in the first space and the at least one pump controller is disposed in the second space adjacent to the first space in the first direction,
wherein each of the plurality of pump devices includes:
a tank in which the photoresist is stored,
a step motor installed in an explosion-proof space separated from the tank, and
a pump housing in which the tank and the step motor are accommodated and including the explosion-proof space,
wherein the pump housing includes:
a pair of surfaces opposing each other in a second direction perpendicular to the first direction, and
at least one air hole disposed on each surface of the pair of surfaces and configured to pass a cooling gas through the explosion-proof space.

17. The semiconductor processing apparatus of claim 16,
wherein the bulkhead structure includes a plate parallel to the second direction and a third direction perpendicular to the first direction and the second direction.

18. The semiconductor processing apparatus of claim 16,
wherein the at least one air hole is connected to the explosion-proof space.

19. The semiconductor processing apparatus of claim 16,
wherein the plurality of pump devices include:
a plurality of first pump devices coupled to a first surface of the system substrate and arranged in the first direction, and
a plurality of second pump devices coupled to a second surface of the system substrate and arranged in the first direction, the second surface opposing the first surface in a third direction perpendicular to the first direction and the second direction, and
wherein each first pump device of the plurality of first pump devices and a corresponding second pump device of the plurality of second pump devices are positioned at a same location in the first direction.

20. The semiconductor processing apparatus of claim 16,
wherein the plurality of pump devices include:
a plurality of first pump devices coupled to a first surface of the system substrate and arranged in the first direction, and
a plurality of second pump devices coupled to a second surface of the system substrate and arranged in the first direction, the second surface opposing the first surface in a third direction perpendicular to the first direction and the second direction, and
wherein each first pump device of the plurality of first pump devices and each second pump device of the plurality of second pump devices are arranged in a zigzag manner in the first direction.
